(19) United States
(12) Patent Application Publication
(10) Pub. No.: US 2003/0234176 A1
(43) Pub. Date: Dec. 25, 2003

(54) Production of carbon and carbon-based materials

(76) Inventor: Jawad Haidar, Campbell (AU)

Correspondence Address: LADAS & PARRY, 224 SOUTH MICHIGAN AVENUE, SUITE 1200, CHICAGO, IL, 60604, US

(21) Appl. No.: 10/333,382

(22) PCT Filed: Jul. 17, 2001
(86) PCT No.: PCT/AU01/00869

(30) Foreign Application Priority Data
Jul. 17, 2000 (AU) PR 2607

(51) Int. Cl. C23C 14/32

(52) U.S. Cl. 204/192.38; 204/298.41

(57) ABSTRACT

The present invention relates to the depositing of carbon and carbon-based materials to produce hard carbon films or carbon-based films. The present methods for producing carbon films and carbon-based films include chemical vapour deposition and filtered arc systems. Both have problems. The present invention discloses a method and apparatus which utilises an arc system comprising an anode and a cathode both of graphite. The graphite anode is used to produce the carbon or carbon-based film precursor material. In order to control the quality and rate of deposition of the precursor material onto a substrate, the arc attachment area to the anode is controlled. Minimising the arc attachment area can increase the rate of deposition.

### FIELD OF THE INVENTION

The present invention relates to the production of carbon and carbon-based materials, and, particularly, but not exclusively, to a method and apparatus for deposition of hard carbon films and carbon-based films.

### BACKGROUND OF INVENTION

Hard carbon films and carbon-based films are used in several industrial applications to enhance performance of coated objects. For example, coating objects with a hard carbon film or a metal-carbide film can give improved resistance to wear. These films may have extreme hardness and a very low coefficient of friction. The films may also have enhanced field emission characteristics so they can be used with such products as field emission cathodes in flat panel displays.

Existing technologies for depositing hard carbon films include chemical vapour deposition (CVD) processes and filtered arc systems.

The CVD process uses a low pressure, low current electrical discharge. In CVD systems, chemical compounds containing the carbon to be deposited are introduced into the system in the gas phase. CVD systems are quite limited because of this gas phase introduction requirement, and also because of a limited deposition area.

In filtered arc systems, the carbon originates from a graphite cathode, together with macroscopic graphite particles. Carbon ions are driven through a curved duct (magnetic filter) and then deposited onto a substrate to form a hard carbon film. A problem with filtered arc systems is that the rate of production of the ions from the arc, because it is a filtered arc, is small and therefore deposition is slow and limited.

For the deposition of other carbon-based films, such as carbide films, existing technologies include also CVD and arc systems.

In CVD systems, all precursor elements to the film, including carbon, are introduced in a gaseous phase using chemical compounds containing the required elements. This has the same problems as for the preparation of hard carbon films by CVD.

In cathodic arc systems, carbon may originate from the electrode, but other compounds need to be introduced in the gas phase using chemical compounds. Further, deposition is slow because of the problems discussed above (slow rate of production of ions).

### SUMMARY OF INVENTION

The present invention provides a method of producing carbon or a carbon-based material, comprising the steps of operating an arc system including an anode from which carbon precursor material or carbon-based precursor material is produced, and a cathode and controlling the arc attachment area on the anode.

Material powder or flakes (carbon or carbon-based material) may be produced by this method. The powder or flakes may be produced by first of all depositing the carbon material or carbon-based material as a layer on a substrate and then scraping the substrate off to form the powder or the flakes. The scraping may occur at the end of the deposition process of depositing the layer or during operation for continuous production of powder or flakes. Further, usually when a film becomes too thick it may disintegrate into flakes.

In an alternative embodiment, the method of the present invention is used for coating a substrate with carbon or a carbon-based material, to provide carbon or carbon-based coatings on any object (substrate).

The method may also be used to deposit thick and very thick layers, to produce carbon or carbon-based bulk materials.

The precursor material is preferably carbon ions and/or carbon atoms. Preferably, the anode electrode is of carbon and is preferably graphite.

The arc attachment to the anode electrode is preferably controlled by being restricted to a particular region of the electrode, and the arc attachment area to the electrode is preferably minimised.

The applicants have found that minimising the size of the arc-anode attachment region increases the energy density at the surface of the electrode which results in the production of more precursor material (ions and/or atoms). This advantageously results in a higher rate of production of materials for deposit on a substrate. There is more precursor material and the material components (ions and/or atoms) have higher velocities (because they are more energised), resulting in higher rates of deposition and also enhanced film properties.

The area of the arc attachment may be adjusted, to control the plasma properties and the rate of production of the precursor material to obtain desired properties for coating, and/or to vary the coating properties (or powder or flake properties where powder or flakes are being produced).

Control of the arc attachment may be achieved by selection of the materials of which the electrode is composed. Preferably, in order to minimise arc attachment to the electrode, the electrode will have material properties of high electrical conductivity, high thermal conductivity and low vapour pressure. To increase the arc attachment area, these material properties need to be selected accordingly (i.e. lower electrical conductivity and thermal conductivity and increased vapour pressure). Where the electrode is graphite, for example, different types of graphite have different material properties and can be selected accordingly for control of the arc attachment area.

Control of the arc attachment may also be implemented by confining the arc by shielding the electrode. For example, if the electrode is)an elongate, rod-like electrode, a nozzle can be placed about the elongate electrode to confine the arc attachment area to the tip of the electrode. Adjustment of the nozzle backwardly or forwardly along the electrode can result in variation of the arc attachment area.

The arc attachment area may also be controlled by passing gas over or about the electrode. The gas is chosen to have an ionisation energy higher or lower than the precursor material. Depending upon the ionisation energy of the gas, the arc attachment area may be large (spread broadly over the electrodes surface) or smaller.

Control of the arc attachment area may also be achieved using magnetic confinement, e.g. a magnetic coil or magnet placed proximate the electrode. Adjusting the proximity of the magnetic coil or magnet to the electrode (or otherwise varying the magnetic field) preferably results in varying the arc attachment area.

Control of the arc attachment area may also be achieved through varying the arc current. For example, the size of the arc-electrode attachment region may decrease when the arc current increases.

Control of the arc attachment may also be achieved by increasing the cooling of the electrode. For example, the size of the arc attachment decreases, where the electrode is a rod electrode, if the length of the rod electrode (between where it is held in an electrode holder and the electrode tip) is decreased.

Control of the arc attachment to the anode may also be achieved from use of different cathode materials. For example, using copper as a material for the cathode and graphite as a material for the anode (with a rod-like anode) the arc-anode attachment region may be reduced. Using a graphite cathode will cause the arc-anode attachment region to spread over a larger area of the anode surface.

A combination of any or all the above control processes may be used to control arc attachment area.

The arc system is preferably mounted in an evacuated chamber which also mounts substrates, which may be objects, to be coated with the carbon or carbon based film.

The present invention further provides an apparatus for producing carbon or a carbon-based material, comprising an arc system including an electrode arranged to have an arc applied thereto, and a cathode, the anode being arranged to produce therefrom a carbon precursor material or carbon-based precursor material as a result of application of the arc, and control means for controlling the arc attachment area to the anode.

The apparatus may produce carbon powder or carbon flakes, as discussed above in relation to the method aspect of this invention. Alternatively, the apparatus may be arranged to produce a carbon coating or carbon-based coating on a substrate, such as an object to be coated. Further, the apparatus may be arranged to produce a thick layer of bulk carbon material or carbon-based material.

The carbon precursor material or carbon-based coating precursor material may be carbon atoms or carbon ions. The electrode is preferably of carbon and is preferably of graphite.

The control means may control the arc attachment area to minimise the arc attachment area to the anode electrode. It may also be arranged to adjust the arc attachment area to the anode electrode.

The control means may comprise the material of which the electrode is composed. As discussed above, material properties can determine the extent of the arc attachment area.

The control means may comprise a shield for confining the arc attachment area, such as a nozzle.

The control means may comprise means for passing a gas about the electrode.

The control means may comprise means arranged to apply a magnetic force, such as a magnetic coil or a magnet, in order to confine the arc attachment.

The control means may comprise means for introducing gasses to the arc system to influence the size of the arc attachment.

The control means may comprise means for adjusting the arc current so as to influence the size of the arc attachment to the electrode.

The control means may comprise a material of which the cathode is composed. As discussed above, the use of different cathode materials can influence the size of the arc attachment to the anode.

A combination of any or all the above control means may be applied.

The system preferably further comprises a chamber mounting the electrode and arranged to mount a substrate, such as an object to be coated.

The present invention further provides an apparatus for producing carbon or a carbon-based material, comprising an arc system, including an anode and a cathode, the anode being arranged to produce carbon-based precursor material or carbon precursor material when an arc is applied between the anode and the cathode. Preferably, the apparatus is arranged to be operated in the absence of hydrogen.

Preferably, the anode is of carbon, and is preferably of graphite.

The apparatus may include any or all of the features in the apparatus discussed above in relation to the first apparatus aspect of this invention.

The present invention yet further provides a method of producing carbon or a carbon-based material, comprising the steps of operating an arc system including an anode and a cathode, so that the anode produces a carbon precursor material or carbon-based precursor material, for coating the substrate.

Preferably, the anode is of carbon, and is preferably of graphite.

Preferably, the method includes the further step of operating the arc system in the absence of hydrogen.

The method of this aspect of the invention may include any or all of the features of the method of the first method aspect of the invention, discussed above.

The present invention provides a method of producing a carbon-based material comprising the steps of operating an arc system including an electrode from which carbon precursor material or carbon-based precursor material is produced, and feeding solid precursor materials into the arc to produce species for production of the carbon-based material.

The solid precursor materials may be metals or any other substances and may be fed into the arc in rod form. Preferably, the solid precursor material enables the production of carbon-based materials in the form of carbides.

The method of this aspect of the invention may include any or all of the features of the method aspects of the invention discussed above.

From a further aspect, the present invention provides an apparatus for producing a carbon based material, comprising an arc system including an electrode from which carbon precursor material or carbon-based precursor material is produced, and a means for feeding solid precursor materials into the arc to produce species for the production of carbon-based materials.

Preferably, the solid precursor material is in rod-form and is preferably fed into the arc at the tip of the electrode so that it melts and provides species for the carbon-based material. Preferably, the solid precursor material is arranged to interact with the arc and the electrode to produce carbides.

### BRIEF DESCRIPTION OF DRAWING

Features and advantages of the present invention will become apparent from the following description of an embodiment thereof, by way of example only, with reference to the accompanying drawings, in which:

FIG. 1 is a schematic diagram of an apparatus in accordance with an embodiment of the present invention;

FIG. 2 is a magnified view of a surface of a film produced in accordance with an embodiment of the present invention;

FIG. 3 is an atomic force micrograph of the film surface; and

FIG. 4 is a graph showing a comparison of Raman spectra of the carbon and graphite anode material.

### DESCRIPTION OF PREFERRED EMBODIMENT

Referring to the drawing, an arc system, generally designated by reference numeral 20, is shown, for producing carbon or carbon-based material for depositing on a substrate. In this embodiment, the substrate is an object 5. The object 5 may be any object on which it is desired to deposit a carbon film or carbon-based film, in order to provide it with specific properties, e.g. conductivity, hardness, a low friction surface, roughness.

The arc system 20 includes an electrode 2, from which a carbon based coating precursor material or carbon coating precursor material is produced when an arc 1 is applied to the electrode 2. In this embodiment, the electrode 2 is a graphite anode.

A control means for controlling an arc attachment area, (indicated by curved line 14), to the electrode 2 is also provided. The control means in this embodiment includes a movable shield 9 (of boron nitrate), the composition of the material of the electrode 2 and also a magnetic coil 16.

In more detail, a cathode 3 is also provided and the arc discharge 1 is operated between the anode 2 and cathode 3. As discussed above, the positively charged arc anode is a rod of graphite. The negatively biased cathode 3 (electrical circuitry for charging the anode 2 and cathode 3 is not shown but will be present in operation, as will be understood by the skilled person) is a disc also of graphite. The anode rod 2 is positioned so that its longitudinal axis coincides with the axis of symmetry of the cathode disc 3.

A shield 4 is positioned about the cathode 3 to prevent particles which may be ejected from the cathode 3 surface from reaching the objects 5 to be coated. Shield 4 is cylindrical (it will be appreciated that it could be other shapes). The line of sight between the tip 15 of the anode rod 2 and the objects 5 to be coated must not intersect with the shield 4.

Electrical circuit means (not shown) are provided to apply a biasing voltage to the objects 5 to be coated, so as to draw ions from the plasma produced by the arc 1. A shutter 6 is placed in front of the objects to be coated, so that coating of the objects 5 can be controlled. A film may be deposited on the objects 5 only when the shutter 6 is open.

Note that a bias voltage may or may not be applied, and when bias voltage is applied it may be a DC bias or an AC bias, depending on the objects 5 material, and also on the resistivity of the coating (and on the required quality of the coating).

The arc system 20 is mounted in a vessel 7 within which the arc system 20 and objects 5 to be coated are placed. A vacuum pumping arrangement (not shown) is provided to keep the pressure in the vessel low. The pressure should be below 0.01 torr.

The arc 1 current depends upon the physical dimensions of the graphite rod anode 2. For an anode of 6 mm diameter, the preferred range of arc current is between 101A and 500A.

The arc 1 may be triggered using an auxiliary rod anode 8. The auxiliary anode 8 is removed or insulated after the arc 1 is fired. Alternatively, an arrangement may be provided so that the anode 2 and/or the cathode 3 are moved together to establish an initial contact between them, and then slowly separated as the arc 1 is triggered. Such arrangements are known for arc systems.

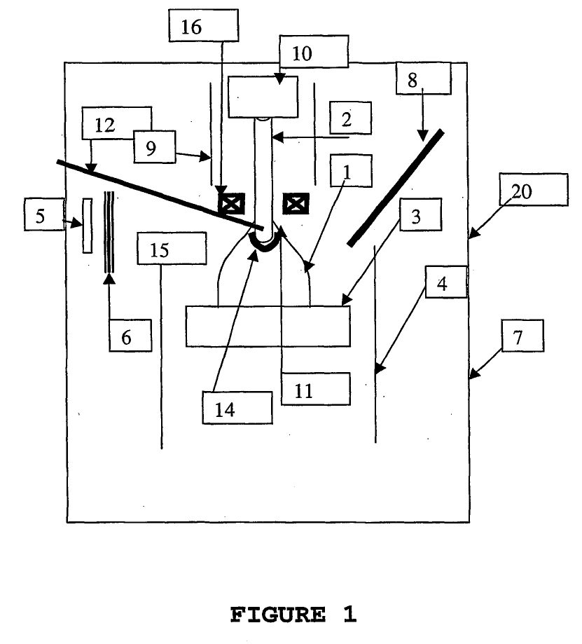

In operation, the tip of the rod anode 2 in the arc-anode attachment region 14 is heated due to condensation on its surface of electrons carrying the arc current from the plasma. The temperature of the surface in this region of the anode 2 reaches a temperature above 3000K and carbon vapour (being in this embodiment the precursor material for the carbon film or carbon-based film) is then omitted due to sublimation or evaporation. An anode rod feeding mechanism 10 continually moves the rod anode 2 towards the cathode 3 so as to compensate for losses from the tip 15 of the rod anode 2 due to sublimation or evaporation, and to maintain a constant arc length for uniform operation. The feeding mechanism 10 may be any suitable mechanism. In this embodiment it includes a stepper motor (which can be controlled appropriately by computer or micro-processor) and a water cooled stainless steel holder for holding the rod 2. In the method and apparatus of this embodiment of the present invention, the arc attachment 14 to the anode 2 is controlled, and in this embodiment it may preferably be minimised. This is done by placing the anode rod so that its axis is symmetrical relative to the cathode 3 surface (which helps minimise the size of the arc anode attachment region 15). Furthermore a shield, in this embodiment in the form of nozzle 9 of boron nitride is placed over an area of the anode rod 2 in order to confine the arc attachment area 14. The nozzle 9, being placed around the anode rod 2, helps prevent the arc from spreading over the anode surface. The size of the nozzle exit 11 and its position relative to the anode rod 2 may be adjusted so that both the plasma properties and the evaporation rate from the anode rod 2 are convenient to obtain optimum film qualities. A coil 16 is placed around the nozzle 9. A current of a few Amperes passing through the coil produces a magnetic field that helps confine the arc-anode attachment to the extreme tip of the anode rod. Minimising the arc-anode attachment area 15 increases the electron number density in front of the anode 2. The resulting increase in the collision frequency between the electrons and the neutral carbon species emanating from the anode due to evaporation help increase the ionisation degree of the plasma. The bias voltage applied to the objects 5 to be coated drives carbon ions from the plasma towards substrate 5, which may enhance film qualities. Also, the increased evaporation from the anode tip together with the compounding effects of the high plasma temperature in front of the anode tip result in an increased pressure in front of the tip, and as a result atomic species from gas phase would have a high kinetic energy which is necessary for deposition of hydrogen free amorphous carbon. Numerical simulations of the process for the arc and electrode configuration in FIG. 1 show that the carbon species emanating from the high pressure zone in front of the anode tip can have velocities in excess of 50 km/s, corresponding to more than 25 eV. It is usually considered that energies of more than 20 eV are needed for deposition of hydrogen free amorphous carbon (McKenzie, D. R., Rep. Prog. Phys., 59 (1996), 1611).

The nozzle 9 can be moved forwardly or backwardly (down or up in the diagram) about the anode 2 in order to adjust the arc attachment region 15 and vary the rate of deposition of the film or the quality of the film being deposited.

Also current through a coil surrounding the nozzle can be varied as the change the resulting magnetic field and hence change the size of the arc-anode attachment region 15 and vary the rate of deposition of the film or the quality of the film being deposited.

Furthermore, in this embodiment, the material of the anode 2 is chosen for properties which result in minimisation of the arc attachment area 14. These properties include high electrical conductivity, high thermal conductivity and low vapour pressure. Graphites with different values for these properties can be chosen as the anode material 2 in order to vary the arc attachment area 14. In one embodiment, the nozzle 9 can be dispensed with and the control of the size of the arc attachment area 14 may be dependent totally on the selection of material of the anode 2. In an alternative embodiment, the choice of the cathode material can be used to influence the size of the arc attachment to the anode. The material may be a certain type of graphite, or may not be graphite at all. For example, copper may be used as the cathode material.

Furthermore, gas may be fed into the vessel 7 through the nozzle 9 surrounding the anode 2, and out through exit 11. The gas material can be chosen so as to have ionisation energy higher or lower than carbon. For a gas that has higher ionisation energy, the arc attachment area 14 spreads over a larger part of the anode 2 surface. For a gas with an ionisation energy lower than carbon, the arc attachment area to the anode is constricted. The choice of gas quality and gas flow may be determined empirically by experimentation. This method of controlling the arc attachment area 14 can be used in conjunction with the nozzle 9 and choice of material of the anode 2, or as the sole control means for controlling the arc attachment area 14. Note that the gas may also include reactive components, such as one or more of the precursor elements of the coating to be coated on the objects 5, (where the coating is not simply a hard carbon coating, but a carbon-based coating such a metal carbide coating, for example).

Another way of controlling the arc attachment area 14 is by using magnetic confinement as discussed above. For example, a magnetic coil or a magnet 16 may be placed in the vessel proximate the anode 2 so that the arc attachment 14 to the anode 2 is confined to a region towards the end of the anode rod 2, facing the cathode 3. Arc confinement may be varied by varying the strength of the magnetic field which may be done by varying the proximity of the magnet or magnetic coil 16 to the anode 2 or by charging the current in the coil. Again, this way of controlling the arc attachment area 14 may be used separately or in conjunction with one or more of the other methods, discussed above.

Other methods of controlling the arc attachment to the anode include controlling the arc current, controlling the length of the electrode (in order to control the cooling of the electrode). These may be used in conjunction with the control means discussed above, or independently.

Precursor materials other than carbon (e.g. for producing metal carbide films) may be introduced into the system in the form of solid precursor material for evaporation in the arc 1. A materials feeding mechanism 12, which may be a tube, or may be a wire or a rod of the precursor material, is fed onto the graphite rod anode 2, either at the tip of the rod 2 (as shown in the diagram) or elsewhere on the lateral surface. As the solid precursor material 12 contacts the hot graphite 2, it melts, resulting in the formation of a layer of molten precursor material (metal, in the case where a metal carbide film is being constructed) over the whole or over part of the graphite rod 2. The area of the anode 2 surface to be covered by the molten materials depends on the required composition of the coating 2. Evaporation from the molten materials and also from the graphite 2 provides the precursor elements for the film. Other precursor elements may also be introduced in a gas phase through exit 11 around the nozzle 9, as discussed above.

Other solid precursor materials may also be introduced in the form of cathode materials. Vapour from the cathode surface can be made to reach the film, hence contributing to the film composition.

The use of solid precursor materials in arc systems for producing carbon, such as this system, for example, is novel.

In the drawing, only a single arc unit including an anode 2 and a cathode 3 is shown. The vessel may contain a plurality of arc units. Objects 5 may be placed anywhere in the vessel where they will be coated.

For deposition of a hard carbon film, the materials feeding mechanism 12 is removed or disabled, so that only carbon will be deposited on the objects 5.

The shutter 6 may be closed during the arc triggering phase. After the arc is started, the shutter 6 may be open and then carbon species from the anode, which may have been excited in the plasma may reach the objects 5. As discussed above, a bias voltage may be applied to the objects 5.

The system of this embodiment may be used to deposit a multi-layer coating on the objects 5. For example, after starting the arc using the triggering agent 8 with the shutter 6 shielding the objects 5, the materials feeding mechanism 12 can deposit materials onto the tip of the rod anode 2. Also, if required, reactive gases may be fed through the nozzle 9 surrounding the anode 2 through exit 11. As the fed solid materials contact the tip of the anode 2, they melt, resulting in the formation of a droplet or a film at the tip of the rod anode 2. Heat transfer from the arc causes the precursor material (which may be a metal, for example, for formation of a metal carbide) to evaporate, to subsequently form a first layer on the surface of the objects 5 to be coated. The layer may contain carbon evaporated from the anode 2. The carbon content may be predetermined by the amount of material deposited on the rod anode 2 using feeding mechanism 12. When the layer is sufficiently thick, the materials feeding mechanism 12 is disabled or is withdrawn, the shutter 6 is closed and the arc is left to operate until the molten materials are removed from the anode rod 2 surface. Then other solid materials may be fed using the mechanism 12 employing the same methodology described above. A plurality of feeding mechanisms similar to mechanism 12 may also be used. When a layer of hard carbon is required, then no solid precursor material is fed onto the anode rod 2, the shutter 6 is opened and a hard carbon layer is deposited.

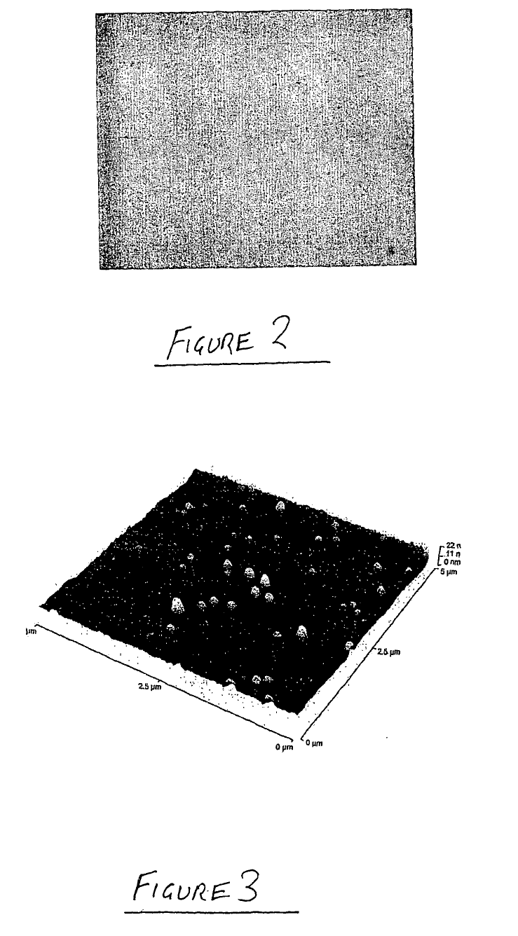

FIGS. 2, 3 and 4 show results of an implementation of an embodiment of the present invention utilising the arrangement of FIG. 1 and using the coil 16 to control the arc-anode attachment. The coil produces a magnetic field of 40 Gauss on its axis. The arc current is 175 Amps and the anode is RWII Ringsdorff rod of graphite with a 6.4 mm diameter. The arc length is kept at around 10 cm.

FIG. 2 shows a magnified view of a carbon film deposited on a silicon substrate (as object 5) corresponding to a surface of 80 μn×100 μn.

FIG. 3 shows an atomic force micrograph taken using an atomic force microscope for the film. It is seen that irregularities in the film surface are small at less than a few tens of nanometers. For this example, nano-indentation measurements indicate a film hardness in excess of 30 GPa.

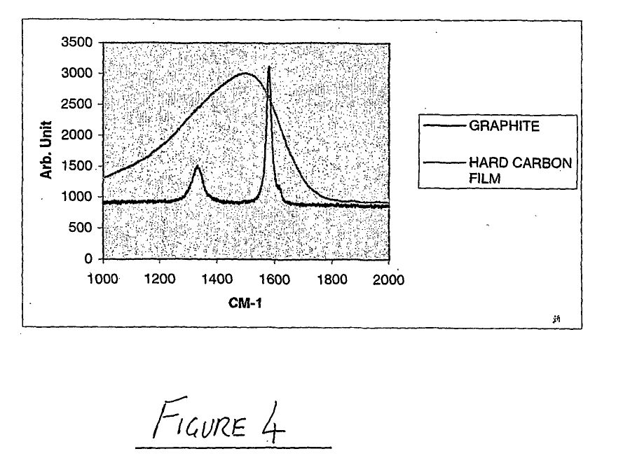

FIG. 4 compares Raman spectra for the a-C film in FIG. 3 and for the graphite materials of the anode rod. It is seen that for the film, there is a broad peak centering around 1488 cm⁻¹, typical for amorphous diamond. As seen in FIG. 4 graphite has two distinct peaks corresponding to the G and D bands. Furthermore, the sp3 content of the film has been determined using Electron Energy Loss measurements (EELS) for a film deposited on a Kill crystal. The measurements indicate an sp3 content around 50%.

The physical characteristics of the process described here have been investigated through numerical simulation of the arc and electrode configuration shown in FIG. 1.

For the experimental conditions mentioned above, we find that the pressure in the region immediately in front of the anode tip increases to more than 0.5 atm, due to the compounded effects of large evaporation from the anode tip, ohmic heating the plasma by the arc current and the effects of the magnetic pinch force due to the magnetic field generated by the arc current. Because of the resulting very steep pressure gradients between the region near the anode tip and the outer regions of the arc, the plasma velocities calculated in the region near the anode tip exceeds 50 km/s in the vertical direction and more than 30 km/s in the radial direction. As the outer region of the arc and the chamber are at a very low pressure, it would be expected that the velocities of the plasma species would be conserved as they travel towards the internal walls of the chamber. The velocities calculated above corresponds to translational kinetic energies of more than 25 eV, which may explain the high sp3 content mentioned above.

If the plasma effects were eliminated we calculate velocities of around 2 km/s, corresponding to an energy of around 0.25 eV. For this case without the effects of the plasma, the physical conditions would be equivalent to those for conventional evaporation of for an arc with a wide arc-anode attachment region. The energy of 0.25 eV calculated here is consistent with experimental observations showing that conventional carbon evaporation is inadequate for deposition of amorphous carbon films.

It will be appreciated that the invention is not limited to using an arc system with an electrode configuration discussed above in the preferred embodiment. Other configurations may be used.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

The claims defining the invention are as follows:

1. A method of producing carbon or a carbon-based material, comprising the steps of operating an arc system including an anode from which carbon precursor material or carbon-based precursor material is produced, and a cathode and controlling the arc attachment area on the anode.

2. A method in accordance with claim 1, comprising the step of producing a carbon coating or carbon-based coating.

3. A method in accordance with claim 1, comprising the step of producing carbon flakes or carbon powder.

4. A method in accordance with claim 1, comprising the step of producing carbon bulk materials.

5. A method in accordance with any one of the preceding claims, wherein the anode is of carbon.

6. A method in accordance with claim 5, wherein the anode is of graphite.

7. A method in accordance with any one of the preceding claims, wherein the step of controlling the arc attachment area includes the step of minimising the arc attachment area.

8. A method in accordance with any one of the preceding claims, wherein the step of controlling the arc attachment area includes the step of adjusting the arc attachment area.

9. A method in accordance with any one of the preceding claims, wherein the step of controlling the arc attachment area includes the step of selecting the material properties of the anode in order to control the arc attachment area.

10. A method in accordance with any one of the preceding claims, wherein the method of controlling the arc attachment area includes the step of shielding the anode with a shield.

11. A method in accordance with any one of the preceding claims, wherein the step of controlling the arc attachment area includes the step of passing a gas over or about the anode.

12. A method in accordance with any one of the preceding claims, wherein the step of controlling the arc attachment area includes the step of utilising a magnetic field.

13. A method in accordance with any one of the preceding claims, wherein the step of controlling the arc attachment area includes the step of controlling the cooling of the electrode.

14. A method in accordance with any one of the preceding claims, wherein the step of controlling the arc attachment area includes the step of controlling the arc current.

15. A method in accordance with any one of the preceding claims, wherein the arc and the cathode electrode is of the same material as the anode electrode.

16. A method in accordance with any one of the preceding claims, wherein the step of controlling the arc attachment area includes the step of selecting the material properties of the cathode anode in order to control the arc attachment area.

17. A method in accordance with any one of the preceding claims, comprising the further step of feeding solid precursor materials to the arc system, which are melted in the arc, whereby to produce carbon-based coatings.

18. A method in accordance with claim 18, wherein the solid precursor material is fed to the electrode, and melts to form a layer or a droplet of precursor material on the electrode, which subsequently vaporises.

19. An apparatus for producing carbon or a carbon-based material, comprising an arc system including an electrode arranged to have an arc applied thereto, and a cathode, the anode being arranged to produce therefrom a carbon precursor material or carbon-based precursor material as a result of application of the arc, and control means for controlling the arc attachment area to the anode.

20. An apparatus in accordance with claim 19, being arranged to produce a carbon coating or carbon-based coating.

21. An apparatus in accordance with claim 21, being arranged to produce carbon flakes or carbon powder.

22. An apparatus in accordance with claim 19, being arranged to produce carbon bulk materials.

23. An apparatus in accordance with any one of claims 19 to 22, wherein the electrode is of carbon.

24. An apparatus in accordance with claim 23, wherein the anode is of graphite.

25. An apparatus in accordance with any one of claims 19 to 24, wherein the control means is arranged to minimise the arc attachment area.

26. An apparatus in accordance with any one of claims 19 to 25, wherein the control means is arranged to enable adjustment of the arc attachment area.

27. An apparatus in accordance with any one of claims 19 to 26, wherein the control means is the material composition of the anode.

28. An apparatus in accordance with any one of claims 20 to 26, wherein the control means comprises a shield for shielding the arc attachment area.

29. An apparatus in accordance with any one of claims 19 to 28 wherein the control means includes means for passing a gas over or about the anode.

30. An apparatus in accordance with any one of claims 19 to 29, wherein the control means includes means arranged to apply a magnetic field.

31. An apparatus in accordance with any one of claims 19 to 30, wherein the control means includes means arranged to control the arc current.

32. An apparatus in accordance with any one of claims 19 to 31, wherein the control means includes means arranged to control the cooling of the anode.

33. An apparatus in accordance with any one of the preceding claims, wherein the cathode electrode is of the same material as the anode electrode.

34. An apparatus in accordance with any one of the preceding claims, wherein the control means is the material composition of the cathode electrode.

35. An apparatus in accordance with any one of claims 19 to 34, further including feeding means for feeding solid precursor materials to the arc system, for melting in the arc, whereby to produce carbon-based coatings.

36. An apparatus in accordance with claim 35, wherein the feeding means is arranged to feed the solid precursor material onto the anode, so that it melts to form a molten droplet or layer on the anode.

37. A method of producing carbon or a carbon-based material, comprising the steps of operating an arc system including an anode and a cathode, so that the anode produces a carbon precursor material or carbon-based precursor material.

38. A method in accordance with claim 37, including the step of producing a carbon coating or carbon-based coating.

39. A method in accordance with claim 37 or claim 38, wherein the anode is of carbon.

40. A method in accordance with claim 37, 38 or 39, wherein the arc system is operated in the absence of hydrogen.

41. An apparatus for producing carbon or a carbon-based material, comprising an arc system including an anode and a cathode, the anode being arranged to produce a carbon precursor material or carbon-based precursor material when the arc is applied to it.

42. An apparatus in accordance with claim 41, being arranged to produce a carbon coating or carbon-based coating.

43. An apparatus in accordance with claim 41 or claim 42, wherein the anode is of carbon.

44. An apparatus in accordance with claim 41, 42 or 43, and being arranged to be operated in the absence of hydrogen.

45. A method of producing a carbon-based material comprising the steps of operating an arc system including an electrode from which carbon precursor or carbon-based precursor material is produced, and feeding solid precursor materials into the arc to produce species for the production of carbon-based materials.

46. An apparatus for producing carbon-based material, comprising an arc system, including an electrode from which carbon precursor material or carbon-based precursor material may be produced, and means for feeding solid precursor materials into the arc to produce species for the production of carbon-based materials.
